(19) United States
(12) Patent Application Publication
(10) Pub. No.: US 2022/0223560 A1
(43) Pub. Date: Jul. 14, 2022

(54) CHIP STRUCTURE, PACKAGING STRUCTURE AND MANUFACTURING METHOD OF CHIP STRUCTURE

(71) Applicant: CHANGXIN MEMORY TECHNOLOGIES, INC., Hefei City (CN)

(72) Inventor: Zengyan FAN, Hefei (CN)

(21) Appl. No.: 17/467,613

(22) Filed: Sep. 7, 2021

Related U.S. Application Data
(63) Continuation of application No. PCT/CN2021/104952, filed on Jul. 7, 2021.

(30) Foreign Application Priority Data
Jan. 14, 2021 (CN) 202110048328.0

(51) Int. Cl. H01L 23/00

(52) U.S. Cl. CPC H01L 24/73; H01L 2224/05583; H01L 24/03; H01L 24/05; H01L 24/08; H01L 24/19; H01L 24/20; H01L 24/24; H01L 2224/73101; H01L 2224/4823; H01L 2224/05017; H01L 2224/08112; H01L 2224/2105; H01L 2224/214; H01L 2224/24225; H01L 2224/0362; H01L 24/48

(57) ABSTRACT

A chip structure, a packaging structure and a manufacturing method of the chip structure are provided. The chip structure includes a base and an electrically conductive interconnection layer. An upper surface of the base is provided with a plurality of bonding pads, and at least two of the bonding pads have same properties. The electrically conductive interconnection layer includes a plurality of electrically conductive interconnection structures. The electrically conductive interconnection structure electrically connects the bonding pads having same properties, and is configured to be electrically connected with a pin on a packaging substrate.

### CROSS-REFERENCE TO RELATED APPLICATIONS

This is a continuation application of International Patent Application No. PCT/CN2021/104952, filed on Jul. 7, 2021, which claims priority to Chinese patent application No. 202110048328.0, filed on Jan. 14, 2021 and entitled “Chip Structure, Packaging Structure and Manufacturing Methods of Chip Structure and Packaging Structure”. The disclosures of International Patent Application No. PCT/CN2021/104952 and Chinese patent application No. 202110048328.0 are incorporated by reference herein in their entireties.

### BACKGROUND

With the development of a semiconductor technology, the spacing of bonding pads on a chip is getting smaller and smaller. When the chip is packaged, the bonding pad on the chip is required to be connected with a pin on a packaging substrate through a lead.

However, when there are more and more bonding pads on the chip, and the spacing between the bonding pads is getting smaller and smaller, the angle of the lead connecting the bonding pad with the pin will be increased, even possibly exceed the lead process capability.

### SUMMARY

The disclosure relates to the technical field of semiconductors, and in particular relates to a chip structure, a packaging structure and a manufacturing method of the chip structure.

According to a first aspect of the disclosure, there is provided a chip structure, which may include a base and an electrically conductive interconnection layer.

An upper surface of the base is provided with a plurality of bonding pads, and at least two of the bonding pads have same properties.

The electrically conductive interconnection layer may include a plurality of electrically conductive interconnection structures. The electrically conductive interconnection structure electrically connects the bonding pads having same properties, and is configured to be electrically connected with a pin on a packaging substrate.

According to a second aspect of the disclosure, there is provided a packaging structure. The packaging structure may include a packaging substrate provided with a plurality of pins, a chip structure described above and leads.

A first end of each of the leads is electrically connected with the pin, and a second end of each of the leads is electrically connected with the electrically conductive interconnection structure.

According to a second aspect of the disclosure, there is provided a manufacturing method of a chip structure including the following operations.

A base having an upper surface provided with a plurality of bonding pads is provided. At least two bonding pads have same properties.

An electrically conductive interconnection layer is formed above the base. The electrically conductive interconnection layer may include a plurality of electrically conductive interconnection structures. The electrically conductive interconnection structure electrically connects the bonding pads having same properties.

### BRIEF DESCRIPTION OF THE DRAWINGS

In order to describe the technical solutions in the embodiments of the disclosure or a conventional art more clearly, the drawings required to be used in descriptions about the embodiments or the conventional art will be simply introduced below. It is apparent that the drawings described below are only some embodiments of the disclosure. Other drawings may further be obtained by those of ordinary skilled in the art according to these drawings without creative work.

FIG. 1 is a top-view schematic structural diagram of a chip structure in an embodiment.

FIG. 2 is a top-view schematic structural diagram of a packaging structure in an embodiment.

FIG. 3A is a schematic diagram of a lead angle in a conventional art.

FIG. 3B is a schematic diagram of a lead angle in an embodiment.

FIG. 4 is a schematic structural diagram of a cross section of a chip structure in an embodiment.

FIG. 5 is a schematic structural diagram of a cross section of a chip structure in another embodiment.

FIG. 6 is a top-view schematic structural diagram of an electrically conductive interconnection structure in an embodiment.

FIG. 7 is a schematic structural diagram of a cross section of a chip structure in yet another embodiment.

FIG. 8 is a schematic structural diagram of a cross section of a packaging structure in an embodiment.

FIG. 9 is a flowchart of a manufacturing method of a chip structure in an embodiment.

FIG. 10A to FIG. 10K are schematic structural diagrams of cross sections of structures obtained during a manufacturing process of a chip structure in an embodiment.

FIG. 11 is a flowchart of a manufacturing method of a packaging structure in an embodiment.

### DETAILED DESCRIPTION

In order to make the disclosure convenient to understand, the disclosure will be described more comprehensively below with reference to the related drawings. The drawings show embodiments of the disclosure. However, the disclosure may be implemented in various forms and is not limited to the embodiments described herein. On the contrary, these embodiments are provided to make the contents disclosed in the disclosure understood more thoroughly and comprehensively.

Unless otherwise defined, all technical and scientific terms used herein have the same meanings as commonly understood by those skilled in the art that the disclosure belongs to. Herein, terms used in the description of the disclosure are only for the purpose of describing specific embodiments and not intended to limit the disclosure.

It is to be understood that when an element or layer is “above”, “adjacent to”, “connected to”, or “coupled to” another element or layer, the element or layer can be directly above, adjacent to, connected to or coupled to the another element or layer, or there may be an intermediate element or layer. On the contrary, when an element is “directly on”, “directly adjacent to”, “directly connected to” or “directly coupled to” another element or layer, there is no intermediate element or layer. It is to be understood that, although various elements, components, regions, layers, doping types and/or parts may be described with terms “first”, “second”, “third”, etc., these elements, components, regions, layers, doping types and/or parts should not be limited by these terms. These terms are used only to distinguish one element, component, region, layer, doping type or part from another element, component, region, layer, doping type or part. Therefore, a first element, component, region, layer, doping type or part discussed below may be represented as a second element, component, region, layer or part without departing from the teaching of the disclosure.

Spatially relational terms such as “below”, “under”, “lower”, “beneath”, “above”, and “upper”, etc. may be used herein for describing a relationship between one element or feature and another element or feature illustrated in the figures. It is to be understood that, in addition to the orientation shown in the figures, the spatially relational terms further include different orientations of devices in use and operation. For example, if the devices in the figures are turned over, elements or features described as being “under” or “beneath” or “below” other elements or features will be oriented to be “on/above” the other elements or features. Therefore, the exemplary terms “under” and “below” may include both upper and lower orientations. Moreover, the device may include otherwise orientation (such as rotation by 90 degrees or in other orientations) and the spatial descriptors used herein may be interpreted accordingly.

As used herein, singular forms “a/an”, “one”, and “the” may include the plural forms, unless other forms are clearly specified in the context. It is also to be understood that, terms such as “comprising/containing” or “having” appoint existence of the stated features, wholes, steps, operations, components, parts or combinations of them, but not excluding the possibility of existence or adding of one or more other features, wholes, steps, operations, components, parts or combinations of them. Meanwhile, in the specification, term “and/or” includes any and all combinations of the related listed items.

The embodiments of the present disclosure are described with reference to a cross section view of a schematic diagram of an ideal embodiment (and an intermediate structure) of the disclosure herein, so that change of shown shapes due to a manufacturing technology and/or tolerance may be predicted. Therefore, the embodiments of the disclosure should not be limited to specific shapes of regions shown herein, but include shape deviation due to the manufacturing technology. For example, an opening shown as a rectangle may be a trapezoid or a converse trapezoid actually, and the shape may be irregular. Therefore, regions shown in the figures are schematic in essence, their shapes do not represent actual shapes of regions of a device, and do not limit the scope of the disclosure.

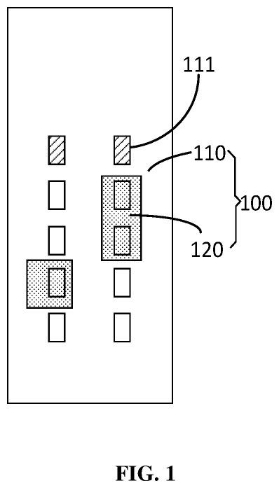

In one embodiment, please refer to FIG. 1, a chip structure 100 is provided. The chip structure may include a base 110 and an electrically conductive interconnection layer 120.

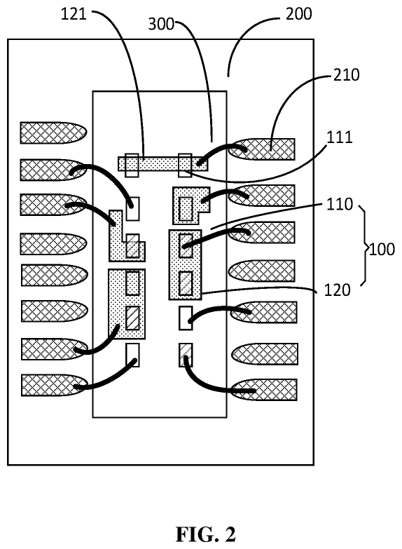

The base 110 may include a substrate (such as a silicon substrate) and components and the like (not shown in the figure) formed on the substrate. An upper surface of the base 110 is provided with a plurality of bonding pads 111, and the bonding pads 111 may electrically lead out the components. Please refer to FIG. 2, the bonding pads 111 are configured to be electrically connected with pins 210 on a packaging substrate 200, so that the chip structure 100 is electrically connected with the packaging substrate 200.

When the chip structure 100 in the conventional art is packaged, each bonding pad 111 thereon is required to be connected with the pin 210 on the packaging substrate 200 through a lead 300, so that an electric signal is obtained.

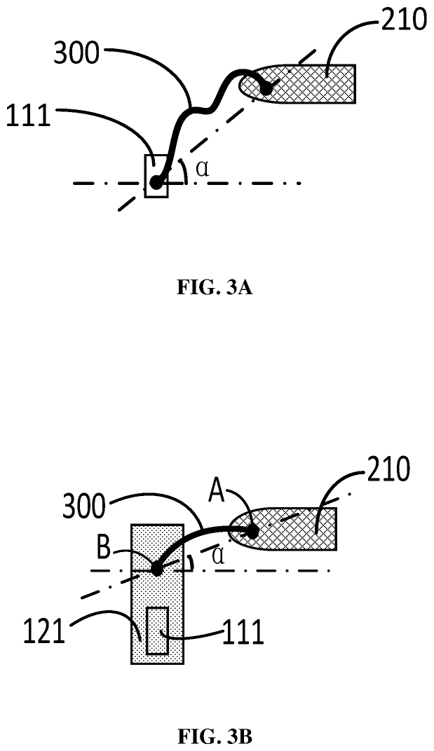

In this way, when there are more and more bonding pads 111 on the chip structure 100, and/or the spacing between the bonding pads 111 is getting smaller and smaller, distances between some bonding pads 111 and the corresponding pins 210 become farther. Therefore, the lead 300 connecting the bonding pad 111 with the corresponding pin 210 is lengthened and has an increased lead angle α, and there may be a depression in the middle of the lead 300 (please refer to FIG. 3A). The lead angle is a horizontal angle of connecting points of the lead 300 with the chip structure 100 and the packaging substrate 200, namely an included angle of a connecting line of two connecting points on a horizontal plane relative to a horizontal direction.

In this case, the leading process difficulty will be increased, and may even exceed the leading process capability. Meanwhile, when the spacing between the bonding pads 111 is getting smaller and smaller, various leads 300 may be short-circuited during a plastic packaging process, due to too dense leads 300.

Referring to FIG. 1 and FIG. 3B, in the chip structure 100 of the disclosure, the electrically conductive interconnection layer 120 is additionally provided. The electrically conductive interconnection layer 120 electrically connects the bonding pads 111 having the same properties. Specifically, the electrically conductive interconnection layer 120 may include a plurality of electrically conductive interconnection structures 121. The bonding pads 111 having same properties may be electrically connected to the same electrically conductive interconnection structure 121.

It is to be understood that the bonding pads 111 having same properties here refer to bonding pads 111 having same functions or effects.

Therefore, please refer to FIG. 2, when the chip structure 100 in the disclosure is packaged, the electrically conductive interconnection structure 121 is connected with the pin 210 on the packaging substrate 200 through the lead 300, so that bonding pads 111 electrically connected with the electrically conductive interconnection structure 121 each may obtain an electric signal on the packaging substrate 200 through the electrically conductive interconnection structure 121.

Meanwhile, during packaging, one end of the lead 300 is connected with the pin 210, and the other end of the lead 300 is electrically connected with the electrically conductive interconnection structure 121. Therefore, an arranging space of the lead 300 may be effectively enlarged, and the leading process may be more flexible. At this time, please refer to FIG. 3B, compared with FIG. 3A, the related lead angle a is effectively reduced, thereby reducing the difficulty in leading process.

Meanwhile, the bonding pads 111 having same properties are electrically connected with the packaging substrate 200 through the same electrically conductive interconnection structure 121, so that the number of the used leads 300 may also be effectively reduced, thereby reducing the packaging cost. Moreover, the reduction of the number of the leads 300 may also effectively prevent the problem of short-circuiting among various leads 300.

It is to be understood that, in the plurality of bonding pads 111 of the chip structure 100 in the embodiments of the disclosure, there may be some bonding pads 111 having different properties from other bonding pads 111. Here, the bonding pads 111 having same properties with other bonding pads 111 are recorded as associated bonding pads, and the bonding pads 111 having different properties from other bonding pads 111 are recorded as independent bonding pads.

During packaging, the independent bonding pad may be directly connected with the pin of the packaging substrate 200 through the lead 300.

Certainly, electrically conductive interconnection structures 121 electrically connected with at least some of independent bonding pads may also be arranged in the electrically conductive interconnection layer 120, so that the independent bonding pad also obtains an electric signal on the packaging substrate 200 through the electrically conductive interconnection layer 120. In this case, the related lead angle of the independent bonding pad may also be effectively improved.

Or, all the bonding pads 111 on the chip structure 100 may also be bonding pads having same properties, which may be specifically set according to actual demands, and is not limited in the disclosure.

Meanwhile, the electrically conductive interconnection layer 120 may completely cover and may also partly cover the independent bonding pad and/or the associated bonding pad, and there is no limitation to this in the disclosure.

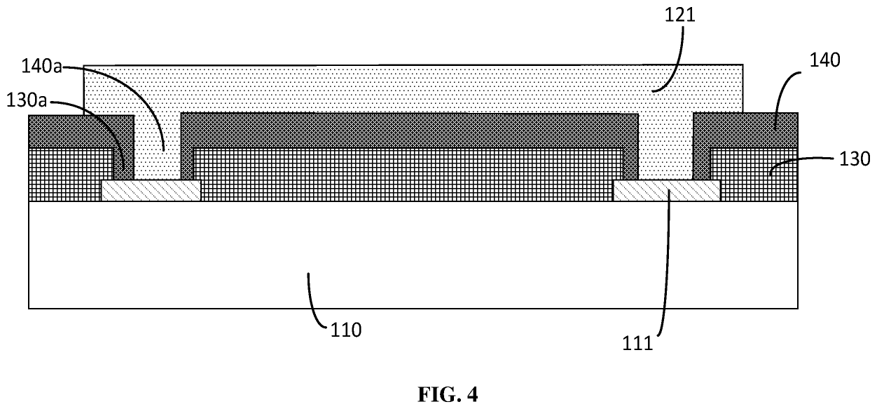

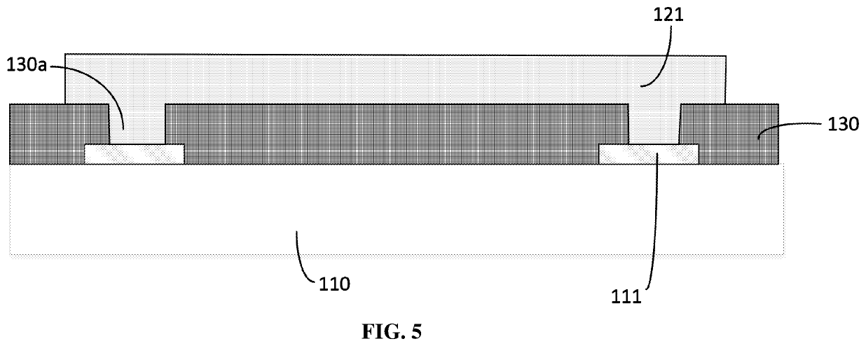

In an embodiment, please refer to FIG. 4 or FIG. 5, the chip structure 100 may also include a first insulating layer 130. First openings 130a are formed in the first insulating layer 130. The first openings 130a expose the bonding pads 111. Moreover, the first insulating layer 130 covers the upper surface of the base 110 on peripheries of the first openings 130a. The electrically conductive interconnection structure 121 electrically connects the bonding pads 111 having same properties through the first openings 130a.

When the chip structure 100 in the embodiments is formed based on the conventional art, the first insulating layer 130 may be a passivation layer. The passivation layer is configured to perform passivation protection, and the passivation layer is usually thin.

Now, please further refer to FIG. 4, the chip structure 100 may also be configured to include a second insulating layer 140. Second openings 140a for exposing the bonding pads 111 are formed in the second insulating layer 140. Moreover, the second insulating layer 140 covers an upper surface of the first insulating layer 130 on peripheries of the second openings 140a.

The electrically conductive interconnection structure 121 electrically connects the bonding pads 111 having same properties through the second openings 140a.

Due to arrangement of the second insulating layer 140, the electrically conductive interconnection layer 120 may be effectively supported, so that the stable performance of the chip structure is ensured. Specifically, the material of the second insulating layer 140 may include, but is not limited to, photoresist.

As an example, an orthographic projection of the second opening 140a on the base 110 is located inside an orthographic projection of the first opening 130a on the base 110. In this case, it may be convenient to fill the second openings 140a with the electrically conductive interconnection layer 120.

Certainly, the relationship between the second opening 140a and the first opening 130a is not limited by the embodiment.

Moreover, the chip structure 100 in the embodiment may also be not formed based on the traditional art. Now, please refer to FIG. 5, a first insulating layer 130 having an enough thickness and having a passivation protection effect may be directly formed in the process, and then, the electrically conductive interconnection layer 120 is directly formed on the first insulating layer 130. In this case, the structure of the chip structure 100 may be effectively simplified, and the procedure of forming the chip structure 100 may be reduced.

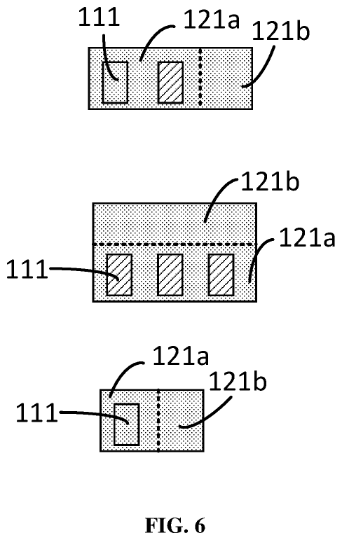

In an embodiment, please refer to FIG. 6, the electrically conductive interconnection structure 121 may include a connection region 121a and a first lead region 121b. The connection region 121a electrically connects the bonding pads 111 having same properties. The first lead region 121b is configured to be electrically connected with the pin 210.

According to the embodiment, the connection region 121a and the first lead region 121b are separately arranged, and therefore by flexibly arranging the first lead region 121b, the lead angle of the leading process is further reduced, and the short-circuiting risk among various leads 300 is further reduced.

In one embodiment, please refer to FIG. 7, the electrically conductive interconnection layer 120 is provided with an electrically conductive layer 1201 and a seed layer 1202. The seed layer 1202 is at least located on surfaces of the bonding pads 111. The electrically conductive layer 1201 is located on a surface of the seed layer. Due to arrangement of the seed layer 1202, a good electroplating process is formed, thereby forming the electrically conductive layer 1201 good in quality.

In one embodiment, a packaging structure is provided, which may include the above-mentioned chip structure 100, packaging substrate 200 and leads 300. Please refer to FIG. 2, one end of the lead 300 is electrically connected with the pin 210 of the packaging substrate 200, and the other end of the lead 300 is electrically connected with the electrically conductive interconnection structure 121 of the chip structure 100.

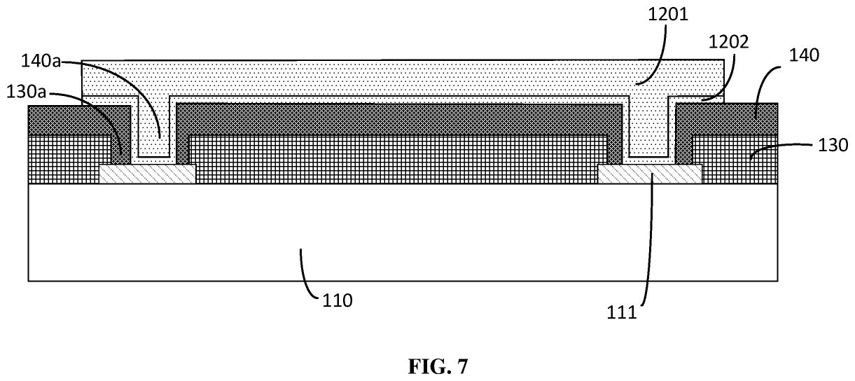

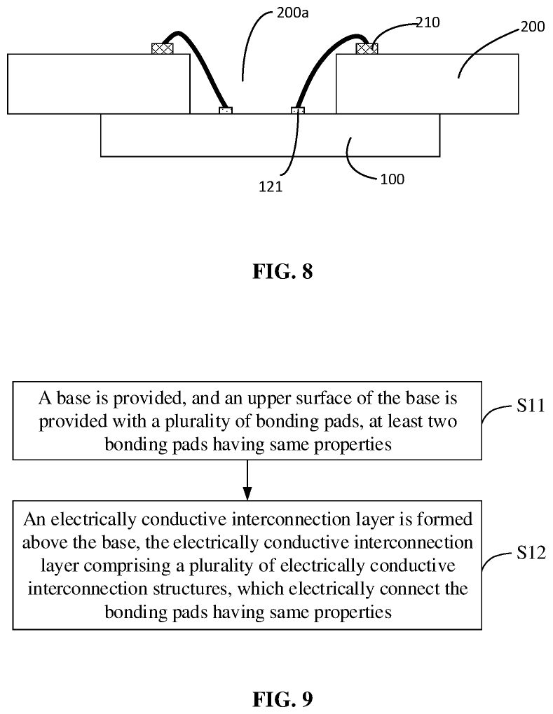

In one embodiment, please refer to FIG. 8, a window 200a is formed in the packaging substrate 200. The pins 210 are formed on one side of the packaging substrate 200. The chip structure 100 is attached to the other side, departing from the pins 210, of the packaging substrate 200. Moreover, each of the leads 300 passes through the window 200a to electrically connect the pin 210 with the electrically conductive interconnection structure 121.

At this time, the packaging structure is in the form of a Window Ball Grid Array (WBGA). Due to arrangement of the chip structure 100, the leading process difficulty of WBGA packaging may be effectively reduced, and the problem of short-circuiting between the leads may be effectively prevented.

In one embodiment, please refer to FIG. 3B, the lead 300 is electrically connected with the pin 210 through a first welding spot A, and is electrically connected with the electrically conductive interconnection structure 121 through a second welding spot B. The horizontal included angle a of a connecting line between the first welding spot A and the second welding spot B is less than 35°, that is, the lead angle is less than 35°. In this case, a good routing arc and a stable process may be obtained.

In an embodiment, the electrically conductive interconnection structure 121 may include a second lead region. The second welding spot is located in the second lead region.

Specifically, the second lead region may be the first lead region 121b mentioned in the above embodiment. Or, in some electrically conductive interconnection structures 121, connecting and leading are carried out in the same region. At this point, the second lead region may also be the electrically conductive interconnection structure 121. There is no limitation to this in the embodiment.

In the embodiment, on a same projection plane, an orthographic projection of the second lead region is at least partly superposed with an orthographic projection of the pin 210 corresponding to the second lead region, and thus the lead angle of the leading process may be effectively reduced.

Furthermore, on the same projection plane, the orthographic projection of the second lead region is located inside the orthographic projection of the pin 210 corresponding to the second lead region. At this point, the direction of a connecting line of two welding spots may be made close to the horizontal direction, so that the lead angle is close to 0°, and thus the leading process is further optimized.

In one embodiment, please refer to FIG. 9, a manufacturing method of a chip structure 100 is provided, which may include the following operations.

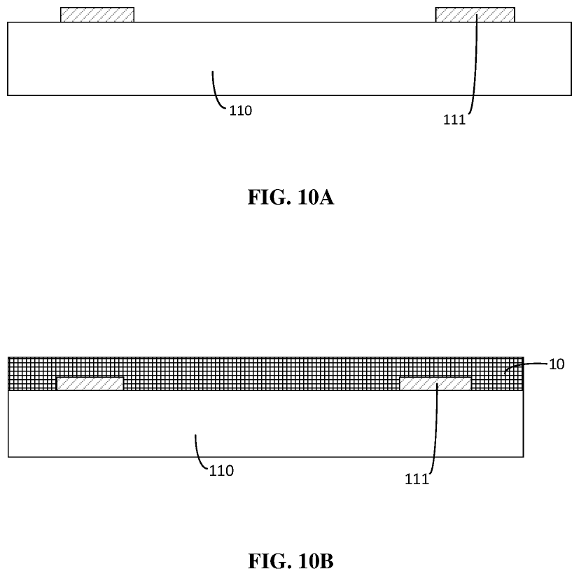

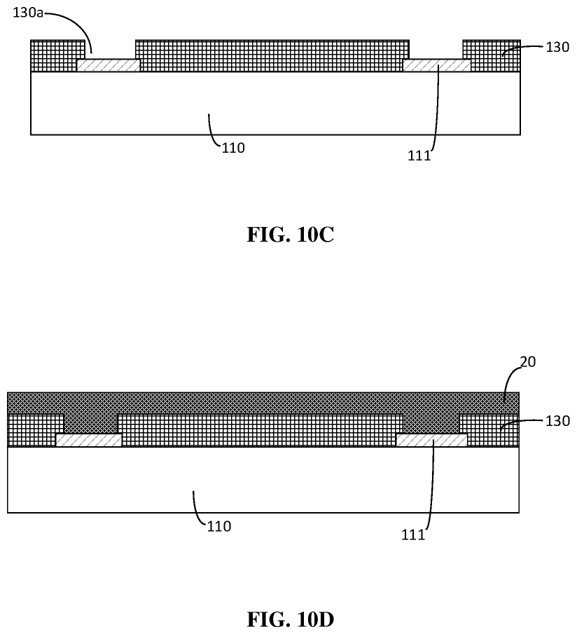

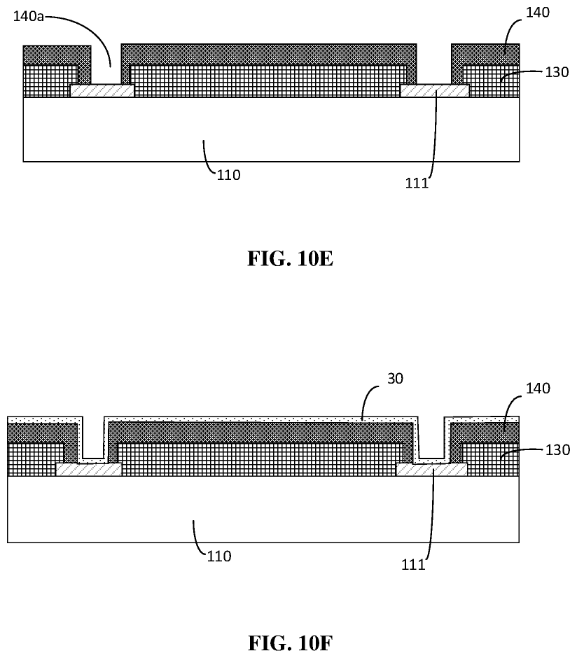

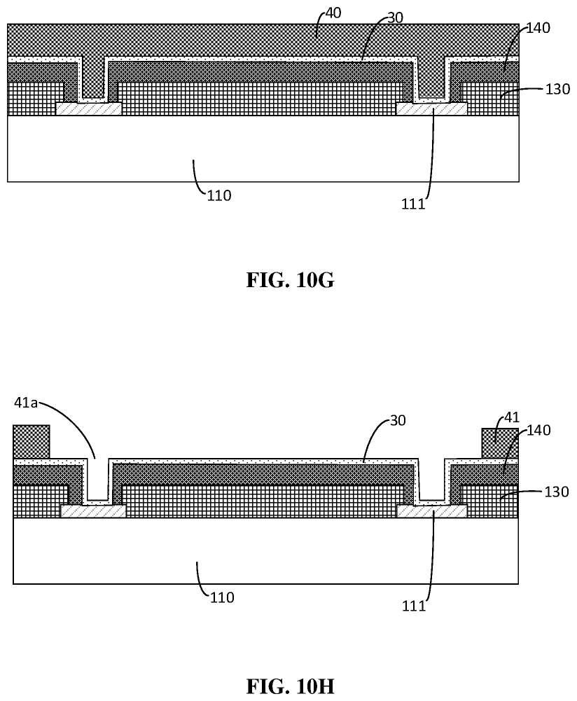

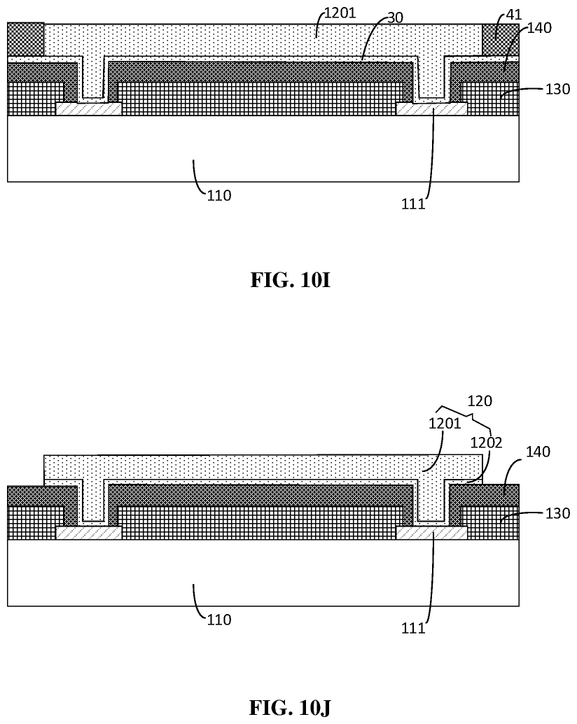

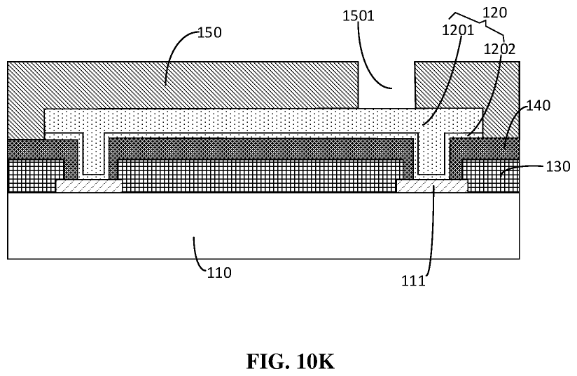

At S11, a base 110 is provided, in which an upper surface of the base 110 is provided with a plurality of bonding pads 111, and at least two bonding pads 111 have same properties, please refer to FIG. 10A.

At S12, an electrically conductive interconnection layer 120 is formed above the base 110. The electrically conductive interconnection layer 120 may include a plurality of electrically conductive interconnection structures 121, and the electrically conductive interconnection structure electrically connects the bonding pads 111 having same properties, please refer to FIG. 10J.

In one embodiment, before S12, the following operations are also included.

At S01, a first insulating material layer 10 is formed on the bonding pads 111 and the upper surface of the base 110 not covered by the bonding pads 111, please refer to FIG. 10B.

At S02, the first insulating material layer 10 is patterned, to form a first insulating layer 130 with first openings 130a, the first openings exposing the bonding pads 111, please refer to FIG. 10C.

At this point, the electrically conductive interconnection structure 121 formed in S12 electrically connects the bonding pads having same properties through the first openings 130a.

In one embodiment, on the basis of the above embodiments, the following operations are further included.

At S03, a second insulating material layer 20 is formed on a surface of the first insulating layer 130 and in the first openings 130a, please refer to FIG. 10D.

At S04, the second insulating material layer 20 is patterned, to form a second insulating layer 140 with second openings 140a, the second openings 140a exposing the bonding pads 111, please refer to FIG. 10E.

The second openings 140a of the second insulating layer 140 are formed in the second insulating material layer 20A.

As an example, the second insulating material layer 20 may be a first photoresist layer. At this time, the patterning of the second insulating material layer may be to perform exposure and development on the first photoresist layer, thereby forming a first patterned photoresist layer as the second insulating layer 140. Photoresist is used as the material of the second insulating layer, so that process steps may be effectively reduced, and the process efficiency may be increased.

In the embodiment, the electrically conductive interconnection structure 121 formed in S12 electrically connects the bonding pads 111 having same properties through the second openings 140a.

Meanwhile, as an example, an orthographic projection of the second opening 140a on the base 110 may be located inside an orthographic projection of the first opening 130a on the base 110.

In one embodiment, the electrically conductive interconnection layer 120 is provided with a conductive layer 1201 and a seed layer 1202. The S12 may include the following operations.

At S121, a seed material layer 30 is formed on a surface of the second insulating layer 140 and surfaces of the exposed-out bonding pads 111, please refer to FIG. 10F.

At S122, a second photoresist layer 40 is formed on a surface of the seed material layer 30, please refer to FIG. 10G.

At S123, the second photoresist layer 40 is exposed to light and is developed, to obtain a second patterned photoresist layer 41. The second patterned photoresist layer 41 has third openings 41a, and the bonding pads 111 having the same properties are exposed to a same third opening 41a, please refer to FIG. 10H.

At S124, an electrically conductive layer 1201 is formed in the third opening 41a, please refer to FIG. 10I.

At S125, the second patterned photoresist layer 41 is removed, and the seed material layer 30 on a periphery of the electrically conductive interconnection layer 120 is removed, in which the remaining seed material layer 30 between the electrically conductive interconnection layer 120 and the second insulating layer 140 is the seed layer 1202, please refer to FIG. 10J.

Moreover, in the embodiments of the disclosure, after the electrically conductive interconnection layer 120 is formed above the base 110 in S12, the following operations are further included.

At S13, a passivation protection layer 150 with a fourth opening 1501 is formed, in which the fourth opening exposes the electrically conductive interconnection structure 121, please refer to FIG. 10K.

The passivation protection layer 150 may perform effective passivation protection on the electrically conductive interconnection layer 120.

As an example, the passivation protection layer 150 may be formed on the electrically conductive interconnection layer 120 and the second insulating layer 140 exposed from the electrically conductive interconnection layer 120. The fourth opening 1501 exposes the electrically conductive interconnection structure 121 for being connected to the lead 300.

Moreover, some specific limitations about the manufacturing method of the chip structure may refer to the foregoing limitations about the chip structure, which is not be elaborated herein.

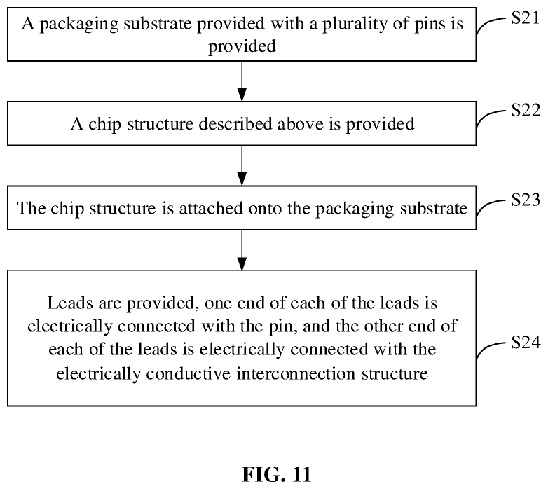

In one embodiment, please refer to FIG. 11, a manufacturing method of a packaging structure is provided, which may include the following operations.

At S21, a packaging substrate 200 provided with a plurality of pins 210 is provided.

At S22, a chip structure 100 described above is provided.

At S23, the chip structure 100 is attached onto the packaging substrate 200.

At S24, leads 300 are provided, and an end of each of leads 300 is electrically connected with the pin 210, and another end of each of the leads 300 is electrically connected with an electrically conductive interconnection structure 121.

In one embodiment, a window 200a is formed in the packaging substrate 200. The pins 210 are formed on one side of the packaging substrate 200, and the chip structure 100 is attached to the other side, departing from the pins 210, of the packaging substrate 200. Moreover, each of the leads 300 passes through the window 200a to electrically connect the pin 210 with the electrically conductive interconnection structure 121.

In one embodiment, the lead 300 is electrically connected with the pin 210 through a first welding spot A, and is electrically connected with the electrically conductive interconnection structure 121 through a second welding spot B. The horizontal included angle of a connecting line between the first welding spot A and the second welding spot B is less than 35°.

In an embodiment, the electrically conductive interconnection structure 121 may include a second lead region, the second welding spot B is located in the second lead region. On a same projection plane, an orthographic projection of the second lead region is at least partly superposed with an orthographic projection of the pin 210 corresponding to the second lead region.

In one embodiment, on the same projection plane, the orthographic projection of the second lead region is located inside the orthographic projection of the pin corresponding to the second lead region.

Moreover, some specific limitations about the manufacturing method of the packaging structure may refer to the foregoing limitations about the packaging structure, which is not be elaborated herein.

It should be understood that, although various steps in flowcharts of FIG. 9 and FIG. 11 are sequentially displayed as indicated by arrows, the steps are not sequentially executed necessarily in the order indicated by the arrows. Unless expressly stated in the description, there are no strict sequence restrictions on the execution of these steps, and these steps may be executed in other order. Moreover, at least part of steps in FIG. 9 and FIG. 11 may include a plurality of steps or a plurality of stages, these steps or stages are not executed necessarily at the same time, and may be executed at different times, and these steps or stages are not necessarily executed sequentially, and may be executed in turn or alternatively with other steps or at least part of steps or stages in other steps.

In descriptions of the specification, description of reference terms such as “an embodiment” refers to that specific features, structures, materials or characterizations described in combination with the embodiments or examples are included in at least one embodiment or example of the disclosure. In the specification, schematic description on the above terms not always refers to same embodiment or example.

Technical features of the above mentioned embodiments may be combined freely. For simplicity of description, not all possible combinations of technical features in the above mentioned embodiments are described. However, as long as there is no contradiction in the combination of these technical features, the combination of these technical features shall fall within the scope recorded in the specification.

The above mentioned embodiments only express some implementation modes of the disclosure. The description of the embodiments are relatively specific and detailed, but cannot thus be understood as limits to the patent scope of the disclosure. It is to be pointed out that those of ordinary skill in the art may further make a plurality of variations and improvements without departing from the concept of the disclosure, which all shall fall within the scope of protection of the disclosure. Therefore, the scope of protection of the disclosure should be determined based on the appended claims.

1. A chip structure, comprising:
a base, an upper surface of the base being provided with a plurality of bonding pads, wherein at least two of the bonding pads have same properties; and
an electrically conductive interconnection layer comprising a plurality of electrically conductive interconnection structures, the electrically conductive interconnection structure electrically connecting the bonding pads having same properties, and being configured to be electrically connected with a pin on a packaging substrate.

2. The chip structure according to claim 1, wherein the chip structure further comprises a first insulating layer, which is provided with first openings for exposing the bonding pads and covers the upper surface of the base on peripheries of the first openings, and wherein the electrically conductive interconnection structure electrically connects the bonding pads having same properties through the first openings.

3. The chip structure according to claim 2, wherein the chip structure further comprises a second insulating layer, which is provided with second openings for exposing the bonding pads and covers a surface of the first insulating layer on peripheries of the second openings, and wherein the electrically conductive interconnection structure electrically connects the bonding pads having same properties through the second openings.

4. The chip structure according to claim 3, wherein an orthographic projection of the second opening on the base is located inside an orthographic projection of the first opening on the base.

5. The chip structure according to claim 1, wherein the electrically conductive interconnection structure comprises a connection region and a first lead region connected with each other, the connection region electrically connecting the bonding pads having same properties, and the first lead region being configured to be electrically connected with the pin.

6. A packaging structure, comprising:
a packaging substrate provided with a plurality of pins;
a chip structure comprising:
a base, an upper surface of the base being provided with a plurality of bonding pads, wherein at least two of the bonding pads have same properties; and
an electrically conductive interconnection layer comprising a plurality of electrically conductive interconnection structures, the electrically conductive interconnection structure electrically connecting the bonding pads having same properties, and being configured to be electrically connected with a pin on a packaging substrate; and
leads each having a first end electrically connected with the pin, and a second end electrically connected with the electrically conductive interconnection structure.

7. The packaging structure according to claim 6, wherein a window is formed in the packaging substrate, the pins are formed on a side of the packaging substrate, the chip structure is attached to another side, departing from the pins, of the packaging substrate, and each of the leads passes through the window to electrically connect the pin with the electrically conductive interconnection structure.

8. The packaging structure according to claim 6, wherein the lead is electrically connected with the pin through a first welding spot, and is electrically connected with the electrically conductive interconnection structure through a second welding spot, and a horizontal included angle of a connecting line between the first welding spot and the second welding spot is less than 35°.

9. The packaging structure according to claim 6, wherein the electrically conductive interconnection structure comprises a second lead region, a second welding spot is located in the second lead region, and wherein on a same projection plane, an orthographic projection of the second lead region is at least partly superposed with an orthographic projection of the pin corresponding to the second lead region.

10. The packaging structure according to claim 9, wherein on the same projection plane, the orthographic projection of the second lead region is located inside the orthographic projection of the pin corresponding to the second lead region.

11. A manufacturing method of a chip structure, comprising:
providing a base having an upper surface provided with a plurality of bonding pads, wherein at least two of the bonding pads have same properties; and
forming an electrically conductive interconnection layer above the base, the electrically conductive interconnection layer comprising a plurality of electrically conductive interconnection structures, and the electrically conductive interconnection structure electrically connecting the bonding pads having same properties.

12. The manufacturing method of the chip structure according to claim 11, before forming the electrically conductive interconnection layer above the base, further comprising:
forming a first insulating material layer on the bonding pads and the upper surface of the base not covered by the bonding pads; and
patterning the first insulating material layer to form a first insulating layer with first openings, the first openings exposing the bonding pads;
wherein the electrically conductive interconnection structure electrically connects the bonding pads having same properties through the first openings.

13. The manufacturing method of the chip structure according to claim 12, before forming the electrically conductive interconnection layer above the base, further comprising:
forming a second insulating material layer on a surface of the first insulating layer and in the first openings; and
patterning the second insulating material layer so as to form a second insulating layer with second openings, the second openings exposing the bonding pads;
wherein the electrically conductive interconnection structure electrically connects the bonding pads having same properties through the second openings.

14. The manufacturing method of the chip structure according to claim 13, wherein an orthographic projection of the second opening on the base is located inside an orthographic projection of the first opening on the base.
